(19) United States
(12) Patent Application Publication
(10) Pub. No.: US 2008/0278144 A1
(43) Pub. Date: Nov. 13, 2008

(54) Monitoring Device to Provide Electrical Access in Restricted Spaces

(75) Inventor: David Hwa-Wei Liu, Herndon, VA (US)

Correspondence Address: Husch Blackwell Sanders, LLP;Welsh & Katz, 120 S RIVERSIDE PLAZA, 22ND FLOOR, CHICAGO, IL, 60606, US

(73) Assignee: Tellabs Vienna, Inc.

(21) Appl. No.: 11/746,183

(22) Filed: May 9, 2007

(51) Int. Cl. G01R 1/06

(52) U.S. Cl. 324/149

(57) ABSTRACT

An elongated, spring-biased, connector clip carries, at a distal end thereof, a plurality of electrical contacts. The clip can be used to access a plurality of terminals or contact points in an electrical unit which are not readily accessible. Distal ends of the clip are spring-biased to move toward one another so as to clamp the electrical terminals or contact points of interest. An open region is provided between the elongated fingers of the clip so that other electrical devices in the case can be avoided during insertion and use of the clip for diagnostic or test purposes.

### FIELD

The invention pertains to electrical devices to provide access to electrical signals for test and monitor purposes. More particularly, the invention pertains to such devices which can be extended into electrical equipment to provide access to an electrical connector which is located in a difficult to reach location.

### BACKGROUND

There is an ongoing need to be able to monitor the operation of electrical equipment for various reasons whether the equipment is in a development phase, an installation phase or a post installation, operational phase.

There are many instances where access ports are readily available through which test or monitoring equipment can be extended to be coupled to appropriate connectors or test points. At times, circumstances develop where the electrical connectors or test points of interest can not be readily accessed without powering the equipment down and removing one or more blocking panels. With the panels removed, the test or monitoring equipment can be coupled to the points of interest and the equipment powered up for test and evaluation.

The above solution does not address circumstance where powering equipment down will result in a loss of data, or a loss of the particular circumstances which are being exhibited and which need to be analyzed for diagnostic and/or corrective purposes.

There thus is an ongoing need for electrical devices which are sized and shaped to provide access to connectors or test points which are not readily available. It would also be preferable if such devices could be safely coupled to the terminals or points of interest without having to power down the associated equipment which might result in a loss of data or the particular circumstances which need to be analyzed and diagnosed.

### SUMMARY

An apparatus which embodies the invention includes first and second elongated, pivotally coupled non-conductive members. A plurality of separate conductive elements is carried by one of the members in the general vicinity of a distal end thereof.

### BRIEF DESCRIPTION OF THE DRAWINGS

FIG. 1 is an isometric view of an electrical unit with a closed cover;

FIG. 2 is an isometric view of the electrical unit of FIG. 1 with the cover open;

FIG. 3 is an enlarged partial view of the unit of FIG. 2 with an interior cover removed;

FIG. 4 is a side elevational view of an electrical connection device in accordance with the invention;

FIG. 5 illustrates the electrical unit of FIG. 3 with the device of FIG. 4 coupled thereto;

FIGS. 6A and 6B illustrate alternate embodiments of the connector device of FIG. 4; and

FIG. 7 illustrates yet another alternate configuration of the device of FIG. 4.

### DETAILED DESCRIPTION

While embodiments of this invention can take many different forms, specific embodiments thereof are shown in the drawings and will be described herein in detail with the understanding that the present disclosure is to be considered as an exemplification of the principles of the invention, as well as the best mode of practicing same, and is not intended to limit the invention to the specific embodiment illustrated.

In one aspect of the invention, an electrical device is formed into the shape of an elongated, generally non-conductive, opposing pair of members or fingers. The devices can be spring-loaded so as to bias distal ends of the members toward one another.

One device which embodies the invention incorporates a probe, a plurality of electrical conductors, which is carried by one of the members adjacent to the distal end thereof. The elements of the probe, which are electrically isolated from one another, can be arranged linearly or arcuately all without limitation. In another aspect of the invention, one or more electrical conductors can be carried by both.

The members can be shaped so at to provide a space or an open region therebetween. The region extends generally from a pivot point of the members to the vicinity of the probe or electrical conductors. When installed on a piece of equipment, the distal ends of the members are biased toward one another with the elements of the probe being biased into contact with the connector elements or test points of the equipment of interest.

In one embodiment of the invention, an elongated clip-like connector can be shaped so as to provide access to a port of an optical network terminal. Such terminals might include an external hinged cover which when opened exposes an internal sheet metal case having an electrical access port. Removing a cover of the access port provides an opening into an internal region of the case.

An electrical connector which embodies the invention can be inserted into the opening in the case, past existing electrical connectors or equipment so as to provide access to one or more contact points within the case which are not otherwise readily available for carrying out diagnostic processing or maintenance activities.

FIG. 1 illustrates an exemplary electrical unit 10 which is located in a closed case which has associated therewith a plurality of electrical or optical inputs and outputs 12. It will be understood that neither the type of electrical unit 10 nor the nature of the electrical or optical inputs and outputs 12 are limitations of the present invention.

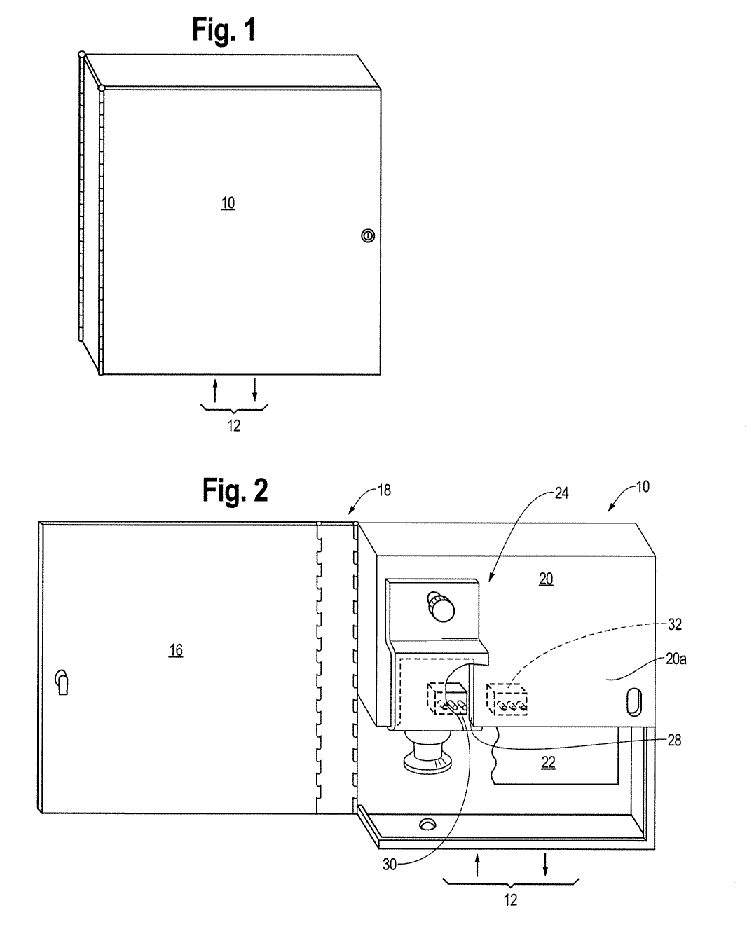

FIG. 2 illustrates the electrical unit 10 after a cover 16, attached to the unit via a hinge 18 has been opened. In the configuration of FIG. 2 an internal case 20 having a variety of connector points 22 associated with the inputs/outputs 12 are readily accessible for testing and monitoring purposes while the unit 10 is perceiving power and carrying out its expected function or functions.

Case 20 also carries an interior removal cover generally indicated at 24 which can carry an electrical or optical terminal indicated generally at 26. The cover 24 can be removed from the case as illustrated in FIG. 3. Once the cover 24 has been removed, an entryway indicated generally at 28 is available into the case 20.

As those of skill in the art will understand, not all the electrical conductors or electrical points of interest are readily available through the entryway or port 28. In particular, as illustrated in FIGS. 2, 3, a connector 30 is generally accessible and available through the port 28. However, an adjacent connector 32, illustrated in phantom, which is located behind or beneath cover 20a of case 20 is not so available.

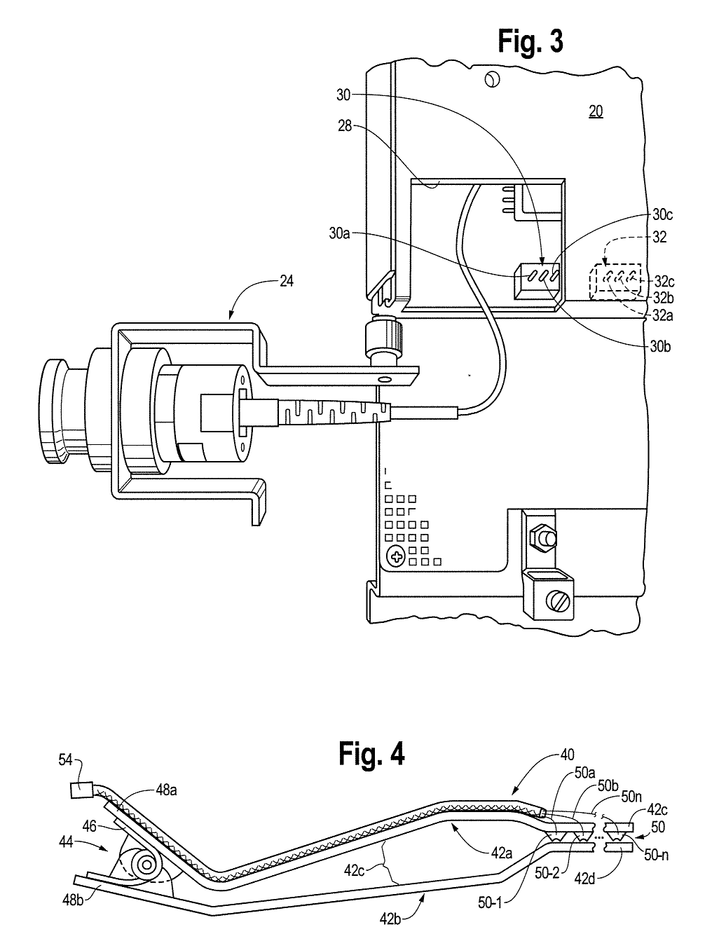

FIG. 4 illustrates an exemplary embodiment of an elongated clip 40, which embodies the invention, and which can be used to obtain convenient and ready access to the electrical connector points of the connector 32. As illustrated in FIG. 4, the clip 40 is formed with the first and second elongated and spaced apart members 42a and 42b. The members 42a, b are joined at a spring-biased pivot point 44. A coil spring 46 can be located at the pivot point 44 to bias respective distal ends 42c, 42d toward one another. The members 42a, b are shaped so as define an open region 42d therebetween.

When proximal ends 48a, 48b are forced toward one another, in opposition to biasing force of the spring 46, the distal ends 42c, 42d separate from one another. As illustrated in FIG. 4, one of the members or fingers 42a carries a plurality of electrical conductors or a multi-element probe 50. The electrical elements of the probe 50 can exhibit a variety of cross-sections such as semi-circular, U-shaped and the like all without limitation. Neither the number of such connectors, nor the shape of their respective cross-sections, represent limitations of the present invention.

Each of members 50-1, -2 . . . -n of the plurality 50 is coupled by an electrical conductor, such as 50a, b, . . . n, to a displaced connector 54. Test and monitoring equipment T can be coupled via the connector 54 to the plurality of contacts 50-1, -2 . . . -n as would be understood by those of skill in the art. Neither the type of test or monitoring equipment nor the analysis associated therewith are limitations of the present invention.

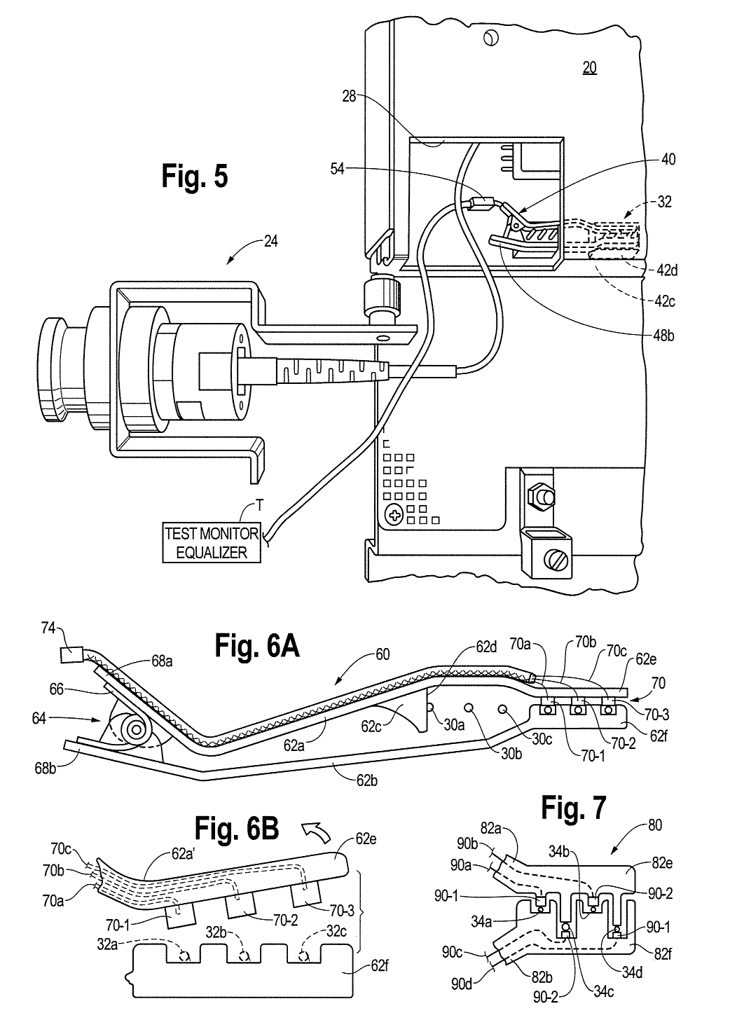

FIG. 5 illustrates exemplary device clip 40 installed in case 20 coupled to contact or connector elements 32a, b, c . . . . As illustrated in FIG. 5, the fingers or elongated elements 42a, 42b of the device 40 extend on each side and past the pins of connector 30 so as to releasibly engage the connector pins 32a, b . . . using the plurality of contacts 50. The connector 40 is positioned relative to the connector 32 by moving it toward the connector element 32 until it contacts one of the pins, namely pin 30a of the connector 30 (best seen in FIG. 3). At this time the proximal ends, 48a, b can be released and the spring 46 will cause the distal ends 42c, 42d to move toward one another thereby bringing the contacts 32a, b, c, into physical and electrical contact with the members of a plurality 50.

Those of skill in the art will understand that the shape of the device 40 is exemplary only. Other shapes come within the spirit and scope of the present invention. For example, the members of the plurality 50 could be arranged arcuately or circularly, as opposed to linearly in FIG. 4 depending on the shape of the electrical contacts or connectors of interest.

FIGS. 6A and 6B illustrate details of an alternate embodiment of a device 60 in accordance with the invention. The device 60 includes first and second spaced apart elongated members 62a, 62b. The member 62a carries a flange or stop 62c with a positioning or abutment surface 62d. Each of the members 62a, 62b has a distal end 62e, 62f. The members 62a, 62b are pivotally attached at a pivot 64. A coil spring 66 is located at the pivot point 64 and biases the distal ends 62e, 62f toward one another. The distal ends 62e, 62f can be spread apart via manually squeezing or clamping together proximal ends 68a, 68b.

The device 60 carries a probe 70 positioned adjacent to the distal ends 62e, 62f. As illustrated in FIGS. 6A, 6B a cable which includes a plurality of conductors 70a, 70b . . . n can be coupled to contacts 70-1, 70-2 . . . -n each of which is carried by member 62a adjacent to distal end 62e. The contacts 70-1, -2 . . . -n can be placed into electrical contact with respective connector members such as the connector members 32a, 32b or 32c which might be located in difficult to reach locations. The device 60 also carries a connector 74 which can be located either near the pivot point 64 or displaced therefrom via the conductors 70a, 70b, 70c for purposes of coupling to displaced, sensing or monitoring equipment.

As illustrated in FIG. 6A the conductive elements and associated cable 70a, 70b, 70c extend along an exterior surface of the member 62a. Alternately, as illustrated in FIG. 6B, such conductive members could be molded into a corresponding member such as 62a′. In the embodiment of FIG. 6B, the conductive probe elements 70-1, -2, -3 slidably engaged U-shaped slots which receive the connector pins 32a, 32b, 32c adjacent to the distal end 62f.

FIG. 7 illustrates yet another connector configuration in a device 80. Elongated fingers or members 82a, 82b having distal end members 82e, 82f each carry a plurality of conductive members 90-1, 90-3 and 90-2, 90-4. Each of the conductive elements of probe 90, 90-1, -2, -3, -4 is coupled to a respective conductor such as 90a, b, c, d which can be used to carry electrical signals sensed off of a connector such as connector 34 having members 34a, b, c, d to displace monitoring or test equipment T.

Those of skill in the art will understand that connector configurations other than those illustrated by connectors 30, 32, 34 which are located in difficult to access locations can be accessed electrically via devices in accordance with the invention. Such devices would carry probes with electrical configurations compatible with the respective connector of interest.

It will also be understood that the coupling connectors such as 54, 74 can be located on, at adjacent to or displaced from the respective devices 40, 60, 80 and the like all without limitation. Further, the contact configurations carried at the respective distal ends such as distal ends 62e, 62f need not be linearly arranged they could be arcuately arranged in accordance with the configuration of the connector of interest to be coupled to.

From the foregoing, it will be observed that numerous variations and modifications may be effected without departing from the spirit and scope of the invention. It is to be understood that no limitation with respect to the specific apparatus illustrated herein is intended or should be inferred. It is, of course, intended to cover by the appended claims all such modifications as fall within the scope of the claims.

1. An apparatus comprising:
first and second, elongated, pivotally coupled non-conducting members; and
a plurality of separate conductive elements carried by one of the members.

2. An apparatus as in claim 1 which includes a spring to bias respective ends of the members toward one another.

3. An apparatus as in claim 1 which includes a cable having first and second ends, one end is coupled to at least some of the conductive elements.

4. An apparatus as in claim 3 with a connector coupled to the other end of the cable.

5. An apparatus as in claim 2 where the non-conducting members each terminate at a respective end with the elements carried adjacent to one of the ends.

6. An apparatus as in claim 5 which includes a cable having first and second ends, one end is coupled to at least some of the conductive elements.

7. An apparatus as in claim 1 where the non-conductive members include a positioning surface positioned adjacent to a pivot point thereof.

8. An apparatus as in claim 7 where the non-conducting members each extend from the pivot point and terminate adjacent a respective gripping region.

9. An apparatus as in claim 1 where the non-conductive members each have an end located distally of the pivot point and where the conductive elements are located adjacent to one of the ends.

10. An apparatus as in claim 9 where the non-conducting members each are formed with a region that curves away from the other member with the region located between the pivot point and a respective end.

11. An apparatus as in claim 10 where the regions form an elongated space between the members.

12. An apparatus as in claim 11 where the conductive elements extend generally linearly between a distal end of the elongated space and the respective end.

13. A monitoring device, comprising:
first and second elongated non-conducting members, each member being pivotally coupled together, each member having a proximal end and a distal end, the members being movable relative to one another between an open position and a closed position;
a spring positioned between the first and second members to bias respective distal ends toward one another, and when the members are in the open position the proximal ends are forced toward one another, in opposition to the biasing force, causing the distal ends to separate from one another; and
a plurality of separate conductive elements coupled to the first member at the distal end.

14. A monitoring device as in claim 13, where a plurality of conductors is coupled to the first member, extending from the distal end to the proximal end, with some members of the plurality being coupled to respective ones of the conductive elements.

15. A monitoring device as in claim 13, where a positioning guide is fixed to the first member at one of a pivot point thereof, or between the spring and the conductive elements.

16. A monitoring device as in claim 13, where the first and second members are oriented so as to define an elongated space between the members.

17. A monitoring device as in claim 13 where the spring is one of a coil spring or a leaf spring.

18. An apparatus comprising:
first and second, elongated, pivotally coupled non-conducting members, each member having a proximal end and a distal end;
means for biasing the distal ends toward one another so that when the proximal ends are forced toward one another, in opposition to the biasing force, the distal ends separate from one another;
means for detecting electrical signals located at the distal end of the first member; and
means for transmitting the detected electrical signals from the distal end to the proximal end of the first member.

19. An apparatus as in claim 18, where the means for transmitting detected electric signals comprise a connector displaced from the distal end of the first member to interface with an external electronic monitoring device.

20. An apparatus as in claim 19 where the means for transmitting includes electrical conductors coupled between the connector and the means for detecting.
